(19) United States
(12) Patent Application Publication
(10) Pub. No.: US 2012/0161806 A1
(43) Pub. Date: Jun. 28, 2012

(54) PROBE MANUFACTURING METHOD, PROBE STRUCTURE, PROBE APPARATUS, AND TEST APPARATUS

(75) Inventors: Hidenori Kitazume, Miyagi (JP); Koji Asano, Saitama (JP)

(73) Assignee: ADVANTEST CORPORATION, Tokyo (JP)

(21) Appl. No.: 13/172,856

(22) Filed: Jun. 30, 2011

(30) Foreign Application Priority Data
Aug. 31, 2010 (JP) 2010-194979

(51) Int. Cl. G01R 31/20; G01R 1/067; H01R 43/16

(52) U.S. Cl. 324/754.11; 29/874; 29/885; 324/755.01

(57) ABSTRACT

Minute probes are created to correspond to the alignment of the input/output terminals of a device under test. A probe manufacturing method of manufacturing a probe, includes: forming a contact section on a probe main body; and shaping at least one of the contact section and the probe main body by cutting by means of a cutting tool. The contact section is formed on a substrate that is to become the probe main body, and the probe manufacturing method further includes: after shaping at least one of the contact section and the substrate that is to become the probe main body, removing the portion of the substrate excluding the probe main body thereby forming a probe.

### BACKGROUND

1. Technical Field

The present invention relates to a probe manufacturing method, a probe structure, a probe apparatus, and a test apparatus.

2. Related Art

Some types of test apparatuses test devices under test, in a semiconductor wafer or in the packaged state. Such a type of test apparatus performs a test by electrically contacting probe needles on the input/output terminals of the devices under test, such as disclosed in Patent Document No. 1.
Patent Document No. 1: Japanese Patent Application Publication No. 2009-2865

This type of test apparatus has to place its probes to correspond to the placement of the input/output terminals of the devices under test. As the pitch for the devices under test becomes narrower, the probes as well as the contacts of the probes have to be manufactured to be minute.

### SUMMARY

Therefore, it is an object of an aspect of the innovations herein to provide a probe manufacturing method, a probe structure, a probe apparatus, and a test apparatus, which are capable of overcoming the above drawbacks accompanying the related art. The above and other objects can be achieved by combinations described in the claims. A first aspect of the innovations may include a probe manufacturing method of manufacturing a probe, including: forming a contact section on a probe main body; and shaping at least one of the contact section and the probe main body by cutting by means of a cutting tool.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows an exemplary configuration of the probe structure 100 according to the present embodiment.

FIG. 2 shows a state in which the probe structure 100 according to the present embodiment is in electrical contact with a device under test 200.

FIG. 3 shows a manufacturing flow of the probe structure 100 according to the present embodiment.

FIG. 4 shows a manufacturing method of a contact section 110 of the probe structure 100 according to the present embodiment.

FIG. 5 shows an example in which a cutting tool 420 cuts the contact section 110 of the probe structure 100 according to the present embodiment.

FIG. 6 shows another example in which the cutting tool 420 cuts the contact section 110 of the probe structure 100 according to the present embodiment.

FIG. 7 shows an example in which the cutting tool 420 cuts the central portion of a probe main body 120 according to the present embodiment.

FIG. 8 shows an exemplary configuration of a probe apparatus 300 according to the present embodiment.

FIG. 9 shows the device under test 200 together with the exemplary configuration of a test apparatus 500 according to the present embodiment.

### DESCRIPTION OF EXEMPLARY EMBODIMENTS

Hereinafter, (some) embodiment(s) of the present invention will be described. The embodiment(s) do(es) not limit the invention according to the claims, and all the combinations of the features described in the embodiment(s) are not necessarily essential to means provided by aspects of the invention.

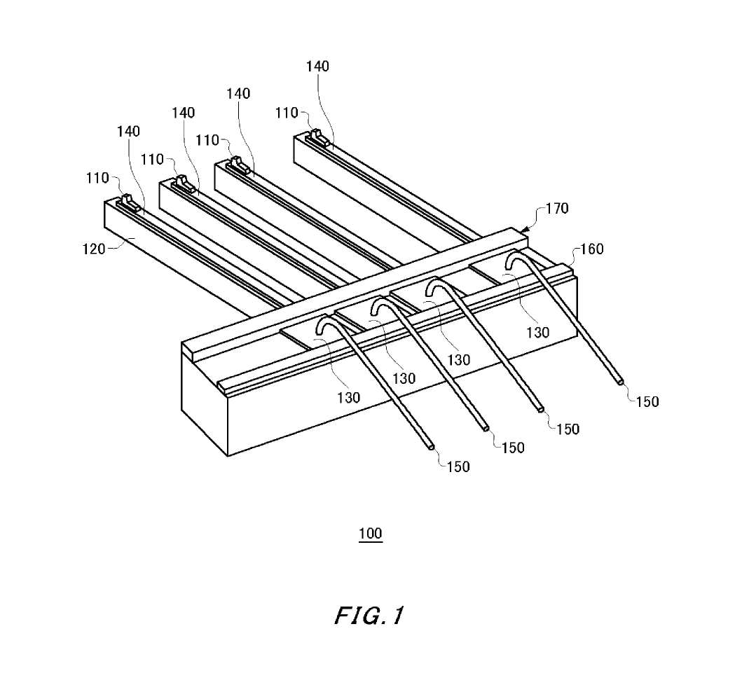

FIG. 1 shows an exemplary configuration of the probe structure 100 according to the present embodiment. The probe structure 100 physically contacts a device under test to be in electrically connection therewith. The probe structure 100 is electrically connected to the substrate mounting it, via a bonding wire 150, thereby forming a probe apparatus. The probe structure 100 includes contact sections 110, a probe main body 120, probe pad sections 130, conducting layers 140, an insulator section 160, and a picker adsorbing section 170.

Each contact section 110 exchanges electric signals with a device under test, by physically and electrically contacting the input/output terminals of the device under test. The contact section 110 may include a plane without any protrusion so as to enable surface contact with the input/output terminals of the device under test, at the plane. Instead, the contact section 110 may have a hemispherical form, or may have a needle-like form whose tip is rounded. The contact section 110 may contain tungsten, palladium, rhodium, gold, white gold, ruthenium, iridium, and/or nickel.

Each contact section 110 is formed on a corresponding probe main body 120. For example, the probe main body 120 is formed from a silicon substrate. Specifically, the probe main body 120 is formed on a semiconductor wafer such as a silicon substrate, using a semiconductor manufacturing technique such as photolithography or etching. As a result, each probe main body 120 can be formed to have a minute form to correspond to the pitch of the input/output terminals of the devices under test.

The probe main body 120 may be formed by being cut by a cutting tool or the like. For example, the probe main body 120 may be formed to have a comp-like shape. Contacts of the contact section 110 are provided respectively on the tips of respective tines of the comb shape of the probe main body 120.

Each probe pad section 130 is electrically connected to a corresponding contact section 110. The probe pad sections 130 may be formed on the surface of the probe main body 120, by means of plating or the like. Each of the plurality of probe pad sections 130 may be provided in correspondence with one of the contact sections 110 formed on the probe main body 120.

Each conducting layer 140 electrically connects a contact section 110 with a probe pad section 130. Each conducting layer 140 may be formed on the surface of the probe main body 120, or inside the probe main body 120. The conducting layers 140 may contain tungsten, palladium, rhodium, gold, white gold, ruthenium, iridium, and/or nickel, substantially the same material as the contact sections 110.

One end of a bonding wire 150 is wire-bonded to a probe pad section 130 to be electrically connected thereto. The bonding wire 150 may contain gold or aluminum. The other end of the bonding wire 150 may be connected to a pad on the substrate on which the probe structure 100 is mounted.

The insulator section 160 is provided on the probe main body 120, to insulate the bonding wires 150 from the probe main body 120. In addition, the insulator section 160 insulates between the plurality of bonding wires 150 respectively connected to the plurality of probe pad sections 130. The insulator section 160 may be formed on the probe main body 120 by photolithography. The insulator section 160 may be an insulation resin such as polyimide or a permanent film resist. The insulator section 160 may apply tension on the bonding wires 150 by contacting them.

The picker adsorbing section 170 is provided to be adsorbed by the picker for adsorbing to hold the probe structure 100 at the time of manufacturing. The picker adsorbing section 170 may be formed on the probe main body 120, and may be simultaneously formed with the insulator section 160. The picker adsorbing section 170 may be made of the same insulation resin as the insulator section 160. In addition, the surface area of the picker adsorbing section 170 may be wider than the surface area of the conducting layers 140.

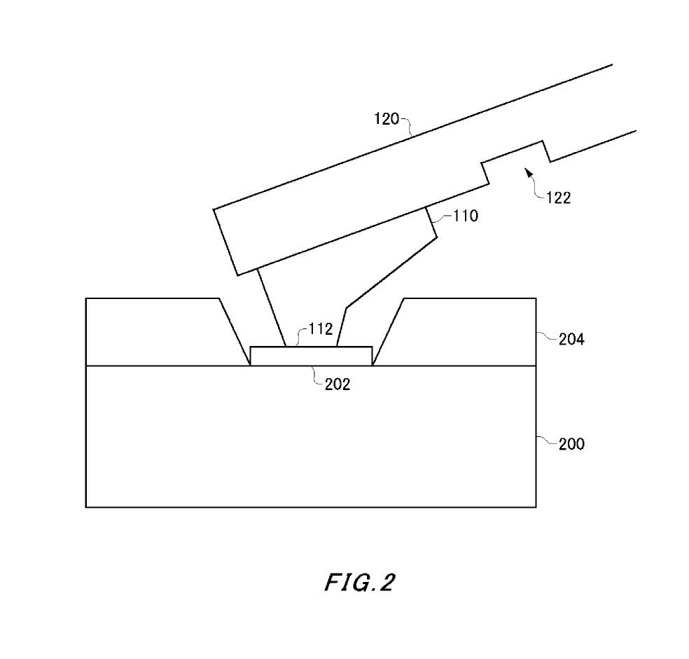

FIG. 2 shows a state in which the probe structure 100 according to the present embodiment is in electrical contact with a device under test 200. The device under test 200 includes one or more pads 202 for inputting and outputting an electric signal, and a protection film 204 for protecting an electronic circuit or the like formed on the surface of the device. The probe structure 100 is desirably equipped with contact sections 110 having a contact width, a contact length, and a form corresponding those of the device under test 200, for protecting them from breakage.

The area of a contacting section 112 of a contact section 110, which can be in contact with a pad 202, is desirably large so as to enable physical connection to allow electrical contact with the pad 202 Desirably, the contacting section 112 should surface-contact the pad 202.

Preferably in an example, the contact surface of the contacting section 112 has a predetermined angle with the probe main body 120, and is not parallel to the probe main body 120. By this configuration, when the probe main body 120 is in contact with the pad 202 at a predetermined angle therebetween, the contact area of the contact section 110 will be larger.

While attempting to establish an electrical connection with the pad 202, the contact section 110 occasionally scrapes off the oxidation film formed on the pad 202, by such an operation as scrubbing by moving along the surface of the pad 202 while in contact thereon. The contact section 110 should therefore desirably be shaped such that can alleviate the scarring (scrub scarring) on the surface of the pad 202 to be comparatively smaller and shallower. For example, a corner of the contact section 110 to be in contact with pad 202 will be cut off, to make its cross section to have nearly a round shape or a spherical shape.

In addition, the flexibility of the probe main body 120 may be adjusted by being equipped with a cut-off section 122 resulting from processing a part of the central portion of the probe main body 120. As a result, the contacting section 112 can be electrically connected to the pad 202 without causing serious scrub scarring. Moreover, even when excess pressure is imposed in the direction to press down the probe main body 120 for some reasons, the probe main body 120 can be bent to absorb the excess pressure, preventing breakage.

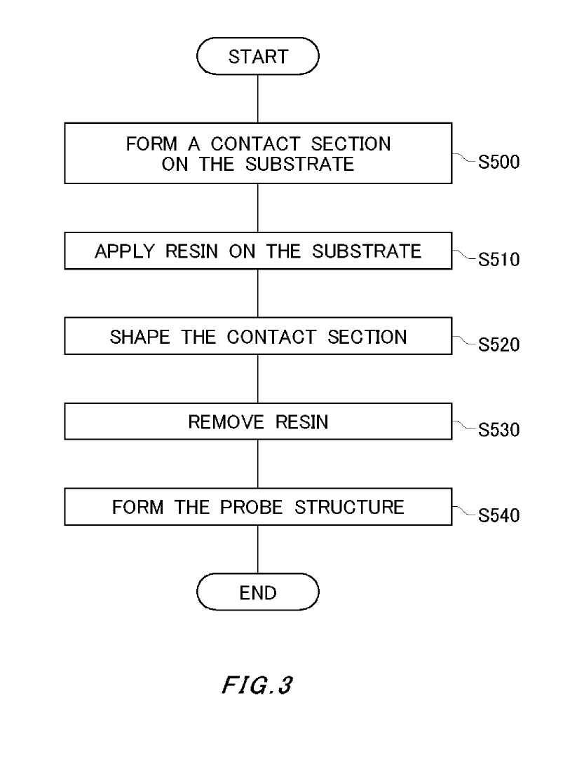

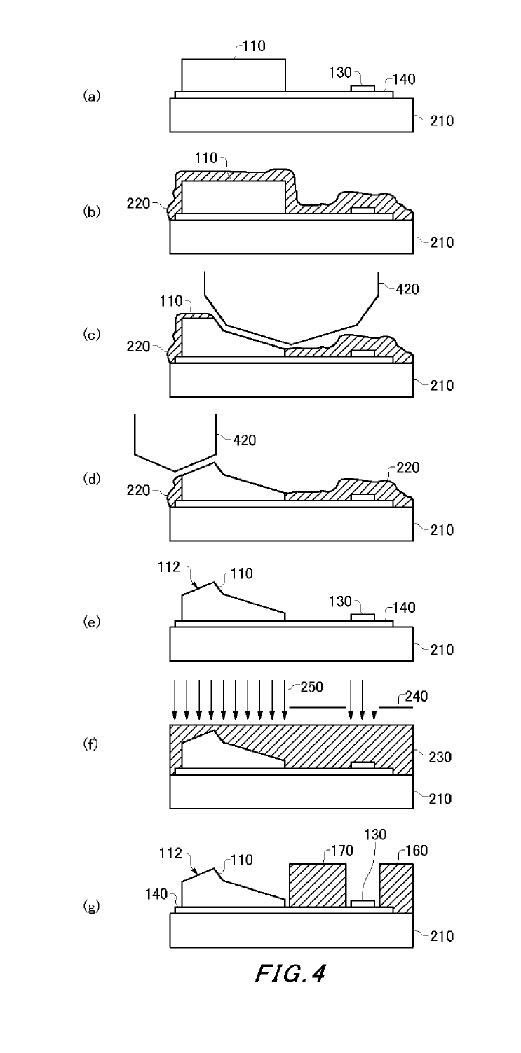

The following describes a method of manufacturing the probe structure 100 according to the present embodiment example. FIG. 3 shows a manufacturing flow of the probe structure 100 according to the present embodiment. FIG. 4 shows a manufacturing method of a contact section 110 of the probe structure 100 according to the present embodiment.

First, a contact section 110 is formed on a substrate that is to be a probe main body 120 (S500). For example, a contact section 110, a probe pad section 130, and a conducting layer 140 are formed on a substrate 210. The substrate 210 may be a silicon wafer. In an example, the conducting layer 140 is formed by evaporation by which a material is heated to be aerified and sublimiated, thereby attaching the material onto the surface of the substrate 210. The probe pad section 130 and the contact section 110 may further be formed on the conducting layer 140 by plating. In (a) of FIG. 4, the state in which the contact section 110, the probe pad section 130, and the conducting layer 140 are formed on the surface of the substrate 210 is shown.

Next, a resin 220 is applied on the substrate 210 (S510). The resin 220 may be a liquid insulation resin such as polyimide or resist. Here, the spin coating method may be adopted by which, after the resin 220 is supplied on the substrate 210, the substrate 210 is rotated at high speeds, thereby making a thin film of the resin 220. The spray coating method may alternatively be adopted in which the resin 220 is sprayed onto the substrate 210. Thus applied resin 220 is solidified by heating the substrate 210. In (b) of FIG. 4, the state is shown in which the resin 220 is applied on the substrate 210 that has already been provided thereon with the contact section 110.

Next, at least one of the contact section 110 and the probe main body 120 is shaped by being cut using the cutting tool 420 (S520). For example, the contact section 110 is cut by the cutting tool 420, to reduce the contact size. This cutting process may be performed so that the length of the upper surface of the contact section 110 in the elongating direction of the probe main body 120 becomes smaller than the length of the portion of the contact section 110 to be in contact with the probe main body 120.

By doing so, the size of the contacting section 112 of the contact section 110 may match the size of the pad 202 of the device under test 200, without reducing the area of the portion of the contact section 110 to be in contact with the probe main body 120. In this way, the contact section 110 can closely attach to the probe main body 120.

The cross section of thus made contact section 110 taken at the elongating surface of the probe main body 120 may be a quadrangle (e.g., rectangle or trapezoid) longer in the elongating direction of the probe main body 120. The contacting section 112 may be formed by being cut on a surface that is not the surface in the elongating direction of the probe main body 120. In addition, one or more surfaces of the contact section 110, other than the contacting section 112, may be cut out, so as to prevent the contact section 110 from contacting the protection film 204. For example, two different surfaces from each other may be cut out, so as to prevent contact with the protection film 204.

Here, the cutting tool 420 set at an angle adjusted to the angle of the structure of the contact section 110 may be abutted to the probe main body 120 in a direction vertical to the elongating direction of the probe main body 120. The cutting tool 420 may be an end mill that can widen the hole in the direction perpendicular to the rotation axis, by rotating to cut the target to be cut with the blade provided on the side surface of the end mill. In (c) and (d) of FIG. 4, the state in which the cutting tool 420 set at an angle adjusted to the angle of the structure of the contact section 110 is abutted to substrate 210 in the vertical direction is shown.

For example, in (c) of FIG. 4, the cutting tool 420 cuts out two different surfaces from each other, for preventing contact with the protection film 204. Although the drawing shows an example in which a cutting tool 420 is used to form the two different surfaces with a single cutting, two different cutting tools 420 may be used instead to respectively cut the two different surfaces. For example, as shown in (d) in FIG. 4, a cutting tool 420 may cut the surface of the contacting section 112.

Here, in the aforementioned cutting process, the cutting tool 420 may also cut the solidified resin 220, after which the still remaining resin 220 is removed (S530). Here, if the resin 220 is obtained by dissolving, in a solvent, a chemical substance that reacts to light, the resin 220 may be removed by dissolving the portion reacted to light incident thereon. Or, the resin 220 may be removed in a liquid developer, a liquid remover, or the like. Accordingly, the shavings or the like from the contact section 110 can be removed with the resin, enabling to cut out the contact section 110 without leaving any minute attachment.

Here, when the viscosity of the resin 220 is too high to unable separation of the shavings of the contact section 110 from the resin 220, the process of solidifying the resin 220 may be eliminated, to cut out the contact section 110 together with the applied resin 220 using the cutting tool 420. In (e) of FIG. 4, the state in which the resin 220 has been removed is shown.

Next, the insulator section 160 and the picker adsorbing section 170 are formed (S540). The insulator resin 230 (e.g., polyimide or a permanent film resist) in a liquid form is applied onto the substrate 210. Here, the spin coating method or the spray coating method may be adopted to apply the insulator resin 230. Next, the substrate 210 is heated, to solidify the applied insulator resin 230.

Then, a mask 240 is used to expose the pattern of the mask 240 on the solidified insulator resin 230. For example, the insulator resin 230 is obtained by dissolving, in a solvent, a chemical substance that reacts to light, and may be a positive type in which the reacted portion will dissolve or a negative type in which the reacted portion will remain. The insulator resin 230 in this example is a positive type, and so the portion having reacted to light 250 will dissolve. In (f) of FIG. 4, the state in which the light 250 is applied through the mask 240 onto the insulator resin 230 is shown.

Next, the exposed substrate 210 is immersed in a liquid developer, to remove the excess insulator resin 230. Accordingly, the insulator section 160 and the picker adsorbing section 170 are formed on the substrate 210. In (g) of FIG. 4, the state in which the insulator section 160 and the picker adsorbing section 170 have been formed on the substrate 210 is shown.

In the above-described embodiment example, the resin 220 and the insulator resin 230 are respectively applied on the substrate 210, and the cutting process with use of the cutting tool 420 and the forming process of the insulator section 160 and the picker adsorbing section 170 are separately performed each time the resin is applied. Alternatively, the cutting process with use of the cutting tool 420 and the forming process of the insulator section 160 and the picker adsorbing section 170 may be sequentially performed to a single insulator resin 230 applied on the substrate 210.

Specifically, the insulator resin 230 is applied on the substrate 210 to be solidified, then at least one of the contact section 110 and the probe main body 120 are cut together with the insulator resin 230 to be shaped, by means of the cutting tool 420. Next, mask 240 is applied on the solidified insulator resin 230, so as to expose the pattern of the mask 240 on the insulator resin 230 in an attempt to remove the unnecessary portion of the insulator resin 230. As a result, the insulator section 160 and the picker adsorbing section 170 can be formed. This method can reduce the number of times of removal of the resin 220 as well as the number of times of applying the resin 220 on the substrate 210.

Next, the portion of the substrate 210 excluding the probe main body 120 is removed (S540). The substrate 210 may be processed either in the dry etching performed using a gas, or the wet etching method performed using a liquid. Alternatively, the substrate 210 may be processed using a cutting tool. The probe structure 100 may be formed to have a plurality of probe needles, by processing the substrate 210 into a comb-like shape using the stated processing methods.

In an example, a round-shaped silicon wafer, being substrate 210, may be processed into a comb-like shape, to complete the probe structure 100 shown in FIG. 1. Here, a plurality of probe structures 100 may be formed from a single substrate 210. In the above explanation of the present embodiment example of manufacturing the probe structure 100, the cutting tool 420 is designed to cut a single contact section 110. Alternatively, the cutting tool 420 can be designed to sequentially cut a plurality of contact sections 110.

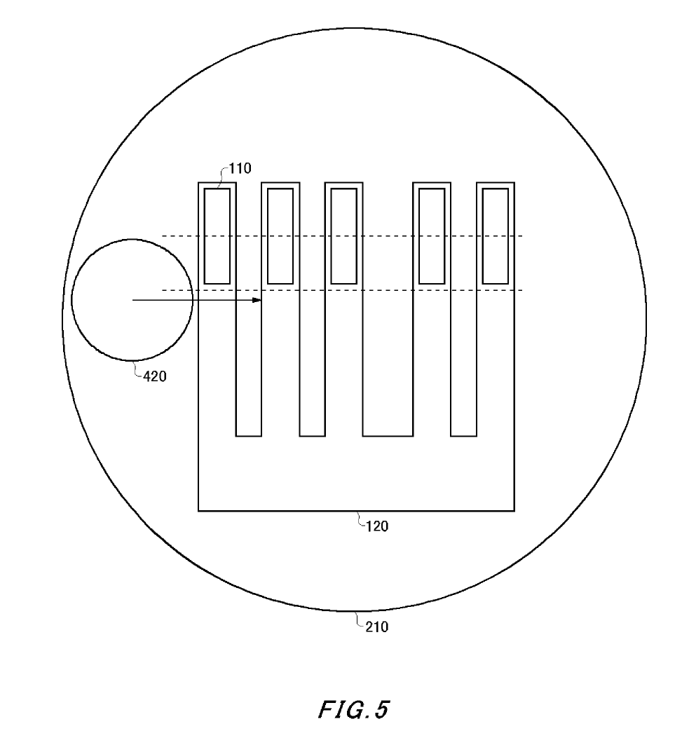

FIG. 5 shows an example in which the cutting tool 420 cuts the contact section 110 of the probe structure 100 according to the present embodiment. The cutting tool 420 may conduct cutting by abutting, in the direction vertical to the elongating direction of the probe main body 120, the cutting tool to the plurality of contact sections 110 of the probes arranged in parallel to each other, to reduce the length of the contacting sections 112 of the contact sections 110 in the elongating direction. The cutting tool 420 may, for example, sequentially cut the plurality of contact sections 110 formed on the substrate 210, by moving in a single direction shown by the arrow in this drawing. This enables creation of contact sections 110 in the same shape.

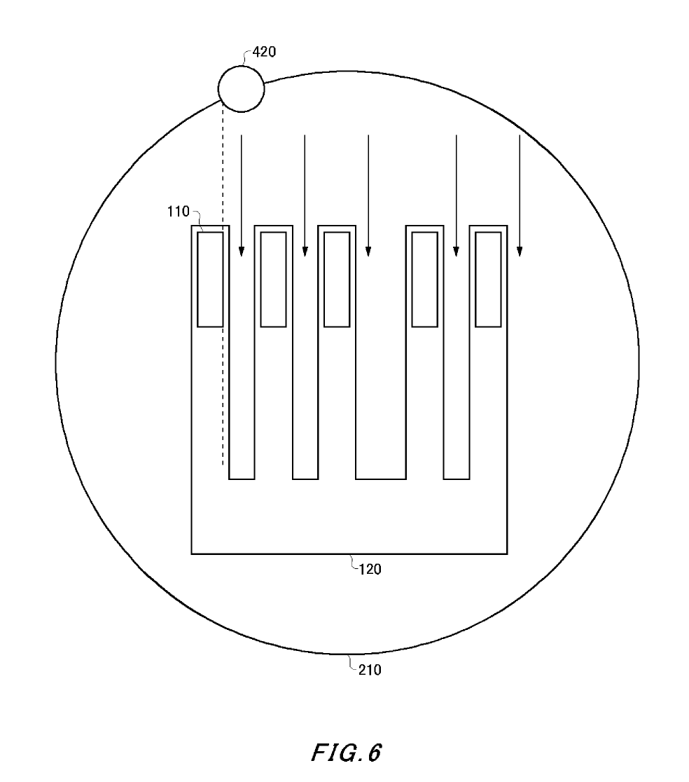

FIG. 6 shows another example in which the cutting tool 420 cuts the contact section 110 of the probe structure 100 according to the present embodiment. The cutting tool 420 cuts out the width of a contacting section 112 of a contact section 110, by abutting, in the elongating direction of the probe main body 120, the cutting tool 420 to the contacts of the plurality of probes arranged in parallel. For example, the cutting tool 420 may move in the direction shown by the arrow in the drawing, to sequentially cut the plurality of contact sections 110 formed on the substrate 210. Accordingly, the contact sections 110 will have the same shape as each other.

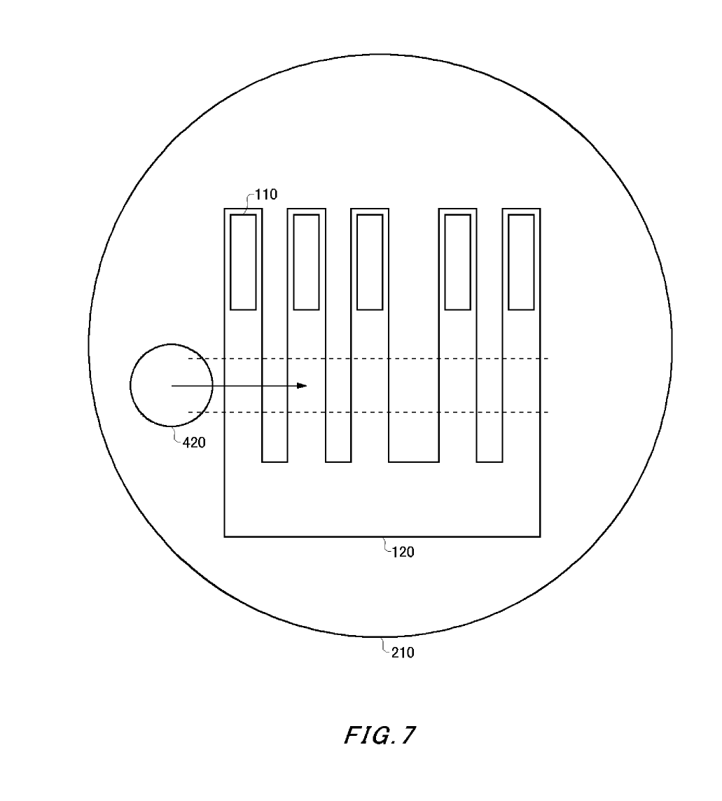

In the above-explained embodiment example of manufacturing the probe structure 100, the contact sections 110 are cut. Alternatively, the cutting tool 420 may cut the probe main body 120. FIG. 7 shows an example in which the cutting tool 420 cuts the central portion of a probe main body 120 according to the present embodiment. The cutting tool 420 cuts at least one portion at the central portion of the probe main body 120 in the direction vertical to the elongating direction of the probe main body 120, thereby forming a cut-out section 122 in the probe main body 120 to adjust the flexibility thereof.

Each of the cutting methods conducted by the cutting tool 420 explained above with reference to FIG. 5 through FIG. 7 is designed to cut either the contact sections 110 on the probe main body 120 or the probe main body 120, which are still on the substrate 210, and so the contact sections 110 and the probe main body 120 hardly have different shapes from one another and can have substantially the same shape as each other, and allows highly accurate processing. After the cutting process by the cutting tool 420, the probe structures 100 may be formed by removing, from the substrate 210, the portion other than the probe shapes in a comb-like shape in the drawing.

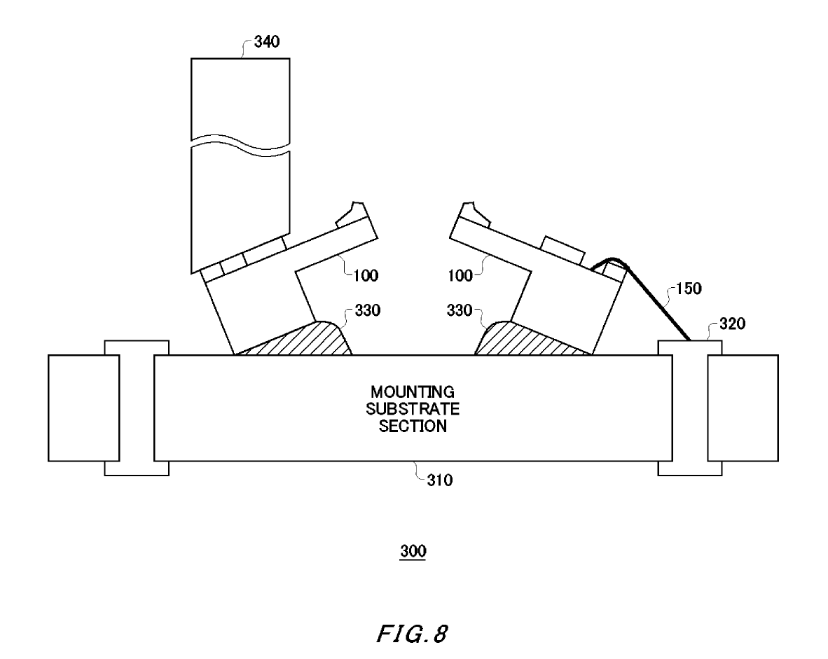

FIG. 8 shows an exemplary configuration of a probe apparatus 300 according to the present embodiment. The probe apparatus 300 is electrically connected to the device under test 200, via the contact sections 110 of the probe structure(s) 100. The probe apparatus 300 includes the probe structure(s) 100, a mounting substrate section 310, and an interconnect section 320.

The mounting substrate section 310 mounts thereon one or more probe structures 100. The mounting substrate section 310 is formed by a material having a comparatively small thermal expansion coefficient, such as ceramic for example. Here, the thickness of the mounting substrate section 310 may be reduced so that temperature difference between the front surface and the rear surface is reduced within the range of the thickness that can maintain a sufficient substrate thickness. Accordingly, warpage on the mounting substrate section 310 attributed to environmental changes such as temperature can be restrained, to be able to contact the plurality of probes to the plurality of input/output sections of a device substantially at the same height and at substantially the same pressure.

The interconnect section 320 exchanges electric signals with the plurality of contact sections 110 included in the probe structure(s) 100. The interconnect section 320 may be formed on the surface of the mounting substrate section 310 on which the probe structure 100 is to be mounted, and may include a pad, a through-hole via, a connector, a circuitry element, or the like/ In addition, the interconnect section 320 may be connected to a circuit formed on the rear surface of the mounting substrate section 310, via the through-hole via or the like. The interconnect section 320 may be electrically connected to the plurality of probe pad sections 130 included in the probe structure(s) 100, via bonding wires 150.

Here, the bonding wire 150 may maintain the state in which the tension is applied by the insulator section 160 by being in contact with the insulator section 160. In addition, the bonding wire 150 is wire-bonded to the probe pad section 130 at one end, and is connected to the interconnect section 320 on the mounting substrate section 310 by being bent in a loop-like shape with its point of support being portion in contact with the insulator section 160.

This design of contacting the bonding wires 150 to the insulator section 160 helps align boding wires 150 in an orderly fashion spatially, and further prevents the bonding wires 150 from being kinked. That is, even when the probe main body 120 has a narrow pitch, the bonding wires 150 can prevent electrical short with the probe main body 120, the adjacent wires, or the like.

Here, the insulator section 160 may be elastic, so that its surface can be concave when applying tension in contact with the bonding wire 150. Due to this configuration, the bonding wire 150 can keep in contact with the insulator section 160, and can prevent electrical short with the adjacent wires even bonded at a narrow pitch.

Here, the probe structure 100 is mounted to the interconnect section 320 using an adhesive 330. The adhesive 330 may be an ultraviolet curable adhesive that is cured when receiving light such as ultraviolet light. The probe structure 100 is moved by being adsorbed by the picker 340, and is attached onto the mounting substrate section 310 in a proper alignment, by means of the adhesive 330.

By providing, on the probe structure 100, the picker adsorbing section 170 having a constant height and wider area than the probe pad sections 130, the picker 340 can firmly and assuredly adsorb the picker adsorbing section 170. Also in the probe structure 100, by making the heights of the insulator section 160 and the picker adsorbing section 170 substantially the same as each other, the picker 340 can also adsorb the insulator section 160, in addition to the picker adsorbing section 170. By this design enabling the picker 340 to firmly and assuredly adsorb the picker adsorbing section 170, the probe structure(s) 100 can also align in a proper alignment on the mounting substrate section 310.

The probe apparatus 300 according to the present embodiment example can mount, with accuracy, a probe structure 100 having contact sections 110 that can contact with the plurality of pads 202 arranged in a narrow pitch of the device under test 200 as well as the pads 202 of a minute size. In addition, the probe apparatus 300 can be connected with the probe pad sections 130 included in the contact sections 110 at a narrow pitch. In the above-explained embodiment example, the probe structure(s) 100 is explained to be mounted with accuracy by means of the insulator section 160 and the picker adsorbing section 170. However, when there is no requirement for the level of precision of positioning of the probe structure(s) 100, there may be no insulator section 160 and/or picker adsorbing section 170.

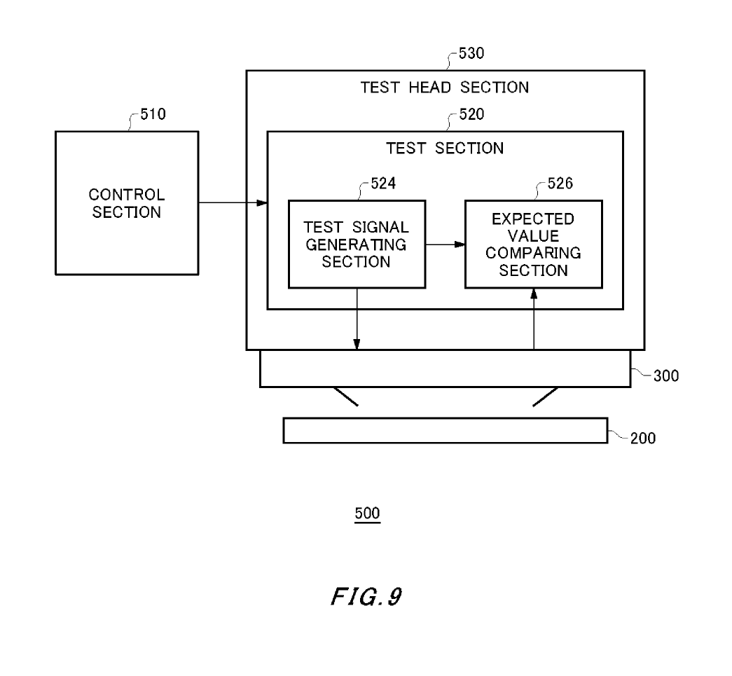

FIG. 9 shows the device under test 200 together with the exemplary configuration of a test apparatus 500 according to the present embodiment. The test apparatus 500 tests a device under test 200 including at least one of an analog circuit, a digital circuit, an analog/digital circuit, a memory, a system on chip (SOC), or the like. The test apparatus 500 inputs, to the device under test 200, a test signal based on the test pattern for testing the device under test 200, to judge pass/fail of the device under test 200 based on the output signal outputted from the device under test 200 according to the test signal. The test apparatus 500 includes a control section 510 and a test head section 530.

The control section 510 transmits, to the test head section 530, a control signal for executing a test. The control section 510 may receive a test result of the test head section 530, and store the test result in the storage apparatus or display the test result on the display apparatus.

The test head section 530 includes a test section 520. The test section 520 tests the device under test 200, by exchanging electric signals with the device under test 200. The test section 520 includes a test signal generating section 524 and an expected value comparing section 526.

The test signal generating section 524 generates a plurality of test signals to be supplied to the device under test 200. The test signal generating section 524 may generate an expected value of a response signal that the device under test 200 outputs according to the test signal. The test signal generating section 524 may test a plurality of devices under test 200, by being connected to the plurality of devices under test 200 via the probe apparatus 300.

The expected value comparing section 526 compares the value of the data received by the test head section 530 to the expected value. The expected value comparing section 526 may receive the expected value from the test signal generating section 524. The test apparatus 500 may judge pass/fail of the device under test 200 based on the result of comparison conducted by the expected value comparing section 526.

The test head section 530 is connected to the device under test 200 including one or more devices, to exchange test signals between the device under test 200 and the test apparatus 500. The test head section 530 includes the probe apparatus 300 according to the present embodiment example.

The test apparatus 500 is electrically connected to the device under test 200 by means of the probe apparatus 300 according to the present embodiment. As a result, the test apparatus 500 can test the device under test 200 having input/output terminals of densely-packed devices or input/output terminals in a complicated arrangement.

While the embodiment(s) of the present invention has (have) been described, the technical scope of the invention is not limited to the above described embodiment(s). It is apparent to persons skilled in the art that various alterations and improvements can be added to the above-described embodiment(s). It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

What is claimed is:

1. A probe manufacturing method of manufacturing a probe, comprising:
forming a contact section on a probe main body; and
shaping at least one of the contact section and the probe main body by cutting by means of a cutting tool.

2. The probe manufacturing method according to claim 1, wherein
the contact section is formed on a substrate that is to become the probe main body, and
the probe manufacturing method further comprises:
after shaping at least one of the contact section and the substrate that is to become the probe main body, removing the portion of the substrate excluding the probe main body thereby forming a probe.

3. The probe manufacturing method according to claim 2, wherein
the shaping includes processing a contact to reduce a contact size by cutting the contact section by means of the cutting tool.

4. The probe manufacturing method according to claim 3, wherein
the contact processing is performed so that the length of an upper surface of the contact section in the elongating direction of the probe is smaller the length of a portion of the contact section to be in contact with the probe.

5. The probe manufacturing method according to claim 4, wherein
in the contact processing, the cutting tool set at an angle adjusted to an angle of a structure of the contact section is abutted in a direction vertical to the elongating direction of a probe.

6. The probe manufacturing method according to claim 3, wherein
in the contact processing, the cutting is performed by abutting the cutting tool to contacts of a plurality of probes arranged in parallel, in a direction vertical to the elongating direction of the probes, thereby reducing lengths of the contacts in the elongating direction.

7. The probe manufacturing method according to claim 3, wherein
in the contact processing, the cutting is performed by abutting the cutting tool to contacts of a plurality of probes arranged in parallel, in a direction parallel to the elongating direction of the probes, thereby cutting the widths of the contacts.

8. The probe manufacturing method according to claim 2, wherein
prior to shaping by means of the cutting tool, the shaping further includes applying a resin on the substrate, and the shaping is performed by cutting the resin too.

9. The probe manufacturing method according to claim 8, wherein
in the applying, the resin is heated to be solidified, and
in the shaping, the solidified resin is cut off by means of the cutting tool, and thereafter a remaining resin is removed.

10. The probe manufacturing method according to claim 1, wherein
in the shaping, at least a portion at a central portion of the probe is cut off in a direction vertical to the elongating direction of the probe, thereby adjusting the flexibility of the probe.

11. A probe structure manufactured by the probe manufacturing method according to claim 1, which is to be electrically connected to a device under test.

12. A probe apparatus which is to be electrically connected to a device under test, comprising:
a mounting substrate section that mounts one or more probe structures according to claim 11; and
an interconnect section that exchanges electric signals with a plurality of contacts of the probe structures.

13. A test apparatus for testing a device under test; comprising:
a test section that tests the device under test by exchanging an electric signal with the device under test; and
a probe apparatus according to claim 12 which is to be electrically connected to the device under test.
